(19) United States
(12) Patent Application Publication
(10) Pub. No.: US 2012/0327698 A1
(43) Pub. Date: Dec. 27, 2012

(54) INTERCONNECTION ARCHITECTURE FOR MEMORY STRUCTURES

(76) Inventor: Frederick Perner, Santa Barbara, CA (US)

(21) Appl. No.: 13/384,004

(22) PCT Filed: Mar. 12, 2010
(86) PCT No.: PCT/US10/27188

§ 371 Date: Jan. 13, 2012

(51) Int. Cl. G11C 5/06

(52) U.S. Cl. 365/72; 365/63

(57) ABSTRACT

An interconnect architecture for connecting read/write circuitry to a memory structure, the interconnect architecture includes a switching layer having a number of access switches arranged in at least one set of two offset switch blocks, the access switches being connected to a first set of parallel wire tracks and a second set of parallel wire tracks intersecting the first set of parallel wire tracks; and a routing layer connecting the switches to a number of access vias of the memory structure; in which four wire tracks are used to select a programmable device of the memory structure.

### STATEMENT OF GOVERNMENT INTEREST

This invention has been made with government support. The government has certain rights in the invention.

### BACKGROUND

Many different types of memory structures have been developed to store electronic data. As the demand for more electronic storage space within a smaller physical space increases, new memory structures are developed to accommodate such demands. One type of memory structure is a crossbar memory structure. A crossbar memory structure generally includes a set of parallel wire segments intersecting a second set of parallel wire segments. Programmable devices capable of storing data may be placed at the crosspoints of each wire segment.

One factor limiting the memory density of crossbar arrays is the addressing and read/write circuitry. In order to access each programmable logic device at a crosspoint within the crossbar array, various electronic components such as decoders and sense amplifiers must connect to each wire segment within the crossbar memory structure. In some cases, the read/write integrated circuitry may be placed underneath a memory structure. However, traditional layout methods may limit the minimal spacing between wire segments of the crossbar memory array.

### BRIEF DESCRIPTION OF THE DRAWINGS

The accompanying drawings illustrate various embodiments of the principles described herein and are a part of the specification. The illustrated embodiments are merely examples and do not limit the scope of the claims.

FIG. 1 is diagram showing an illustrative crossbar array, according to one embodiment of principles described herein.

FIG. 2 is a diagram showing an illustrative multi-layer circuit, according to one embodiment of principles described herein.

FIG. 3 is a diagram showing an illustrative set of two offset switch blocks, according to one embodiment of principles described herein.

FIG. 4 is a diagram showing an illustrative top view of a switch block layer, according to one embodiment of principles described herein.

FIG. 5 is a diagram showing an illustrative top view of a horizontal wire track layer, according to one embodiment of principles described herein.

FIG. 6 is a diagram showing an illustrative top view of a vertical wire track layer, according to one embodiment of principles described herein.

FIG. 7 is a diagram showing an illustrative top view of a routing layer to connect to a disjointed crossbar array, according to one embodiment of principles described herein.

FIG. 8 is a diagram showing illustrative multiple sets of switch blocks in a memory array, according to one embodiment of principles described herein.

FIG. 9 is a diagram showing an illustrative routing interconnect layer for a memory array having multiple sets of switch blocks, according to one embodiment of principles described herein.

FIG. 10 is a diagram showing an illustrative disjointed crossbar array, according to one embodiment of principles described herein.

FIG. 11 is a diagram showing an illustrative aligned crossbar array, according to one embodiment of principles described herein.

FIG. 12 is a diagram showing an illustrative routing layer for an aligned crossbar array, according to one embodiment of principles described herein.

FIG. 13 is a diagram showing an illustrative switch block with access switches having both an N channel MOSFET device and a P channel MOSFET device, according to one embodiment of principles described herein.

FIG. 14 is a flow chart showing an illustrative method for connecting read/write circuitry to a memory structure, according to one embodiment of principles described herein.

Throughout the drawings, identical reference numbers designate similar, but not necessarily identical, elements.

### DETAILED DESCRIPTION

As mentioned above, one factor limiting the memory density of crossbar arrays is the addressing circuitry. In order to access each programmable crosspoint to perform reading and writing operations, various electronic components such as decoders and sense amplifiers must connect to each wire segment within the crossbar memory structure. In some cases, the read/write integrated circuitry may be placed underneath a memory structure. However, traditional layout methods may limit the minimal spacing between wire segments of the crossbar memory array.

In light of this and other issues, the present specification relates to methods and systems for connecting read/write circuitry to a memory structure in a manner that allows for higher density memory arrays. According to certain illustrative embodiments, the read/write circuitry may be connected to a switching layer. The switching layer may include a number of access switches arranged in at least one set of two offset switch blocks. The access switches may be connected to both a first set of parallel wire tracks and a second set of parallel wire tracks intersecting the first set of parallel wire tracks. Electrical signals sent along the wire tracks may be used to turn the access switches on or off. The access switches may also be connected to a routing layer. The routing layer may be used to route read/write signals passing through the access switches to access vias connected to the memory crossbar array. As the positions of the access vias may be limited by the design and structure of the crossbar array, the routing layer may properly route the read/write signals from the access switch positions within the switching layer to the access vias.

Through use of a system or method embodying principles described herein, the access switches may be laid out independent of the associated memory structure. Thus, the access switches may be laid out in a more condensed and efficient manner. As a result, a memory structure may be designed on a smaller scale, thus providing more memory storage space within a smaller amount of physical space.

In the following description, for purposes of explanation, numerous specific details are set forth in order to provide a thorough understanding of the present systems and methods. It will be apparent, however, to one skilled in the art that the present apparatus, systems and methods may be practiced without these specific details. Reference in the specification to “an embodiment,” “an example” or similar language means that a particular feature, structure, or characteristic described in connection with the embodiment or example is included in at least that one embodiment, but not necessarily in other embodiments. The various instances of the phrase “in one embodiment” or similar phrases in various places in the specification are not necessarily all referring to the same embodiment.

Throughout the specification and in the appended claims, the term “read/write circuitry” is to be broadly interpreted as a group of electronic components used to perform reading and writing operations on a programmable logic device. Read/write circuitry may include, but is not limited to, decoder circuits and sense amplifiers.

Throughout this specification and in the appended claims, the term “memory structure” is to be broadly interpreted as the physical structure of an electronic circuit designed to store digital data. A memory structure may include a number of programmable devices configured to be set to a number of different states.

Throughout this specification and in the appended claims, the term “crossbar array” is to be broadly interpreted as a number of lower wire segments configured to intersect a number of upper wire segments. A programmable logic device may be present at each crosspoint between an upper wire segment and a lower wire segment. The term “disjointed crossbar array” may refer to a crossbar array in which the end crosspoints of an upper wire segment do not intersect the same lower wire segments as the end crosspoints of an adjacent parallel upper wire segment or vice versa. Conversely, the term “aligned crossbar array” may refer to a crossbar array in which the end crosspoints of an upper crossbar array intersect the same lower wire segments as the end crosspoints of an adjacent upper crosspoint or vice versa.

Throughout this specification and in the appended claims, the term “access switch” may refer to an electrical switch which may be in an ON state or an OFF state. An ON state may allow signals to pass through while an OFF state may prohibit signals from passing through. A switch may include, but is not limited to, a transistor.

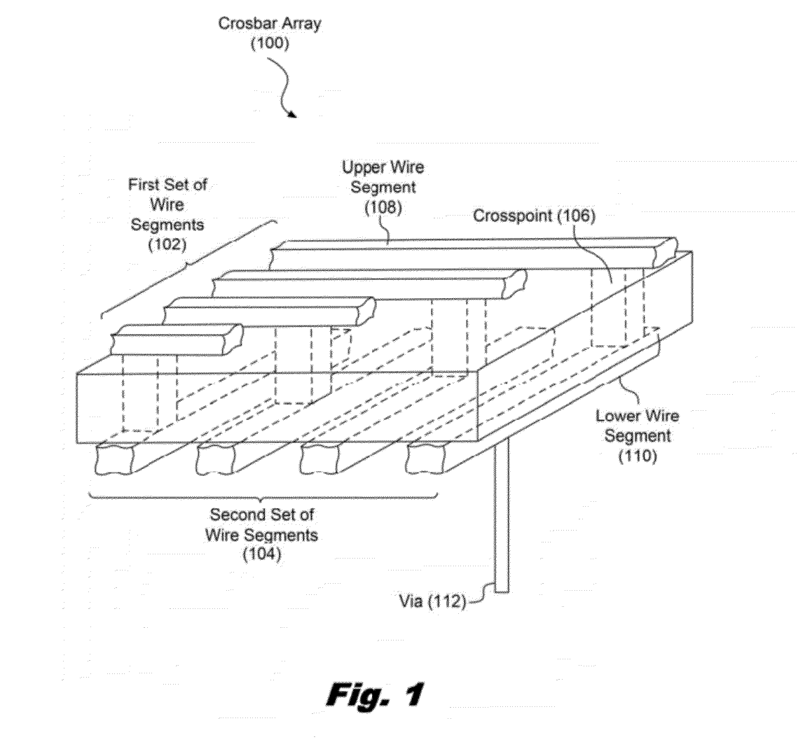

Referring now to the figures, FIG. 1 is a diagram showing illustrative crossbar memory architecture (100). According to certain illustrative embodiments, the crossbar architecture (100) may include an upper set of wire segments (102) which may generally be in parallel. Additionally, a second set of wire segments (104) may be generally perpendicular to and intersect the first set of wire segments (102). Programmable crosspoint devices (106) may be formed at the intersection between an upper wire segment (108) and a lower wire segment (110).

According to certain illustrative embodiments, the programmable crosspoint devices (106) may be memristive devices. Memristive devices exhibit a “memory” of past electrical conditions. For example, a memristive device may include a matrix material which contains mobile dopants. These dopants can be moved within a matrix to dynamically alter the electrical operation of an electrical device. The motion of dopants can be induced by the application of a programming condition such as an applied electrical voltage across a suitable matrix. The programming voltage generates a relatively high electrical field through the memristive matrix and alters the distribution of dopants. After removal of the electrical field, the location and characteristics of the dopants remain stable until the application of another programming electrical field. For example, by changing the dopant configurations within a memristive matrix, the electrical resistance of the device may be altered. The memristive device is read by applying a lower reading voltage which allows the internal electrical resistance of the memristive device to be sensed but does not generate a high enough electrical field to cause significant dopant motion. Consequently, the state of the memristive device may remain stable over long time periods and through multiple read cycles.

Additionally or alternatively, the programmable crosspoint devices may be memcapacitive devices. According to one illustrative embodiment, memcapacitive devices share operational similarities with memristors, except the motion of dopants within the matrix primarily alters the capacitance of the device rather than its resistance.

According to certain illustrative embodiments, the crossbar architecture (100) may be used to form a non-volatile memory array. Non-volatile memory has the characteristic of not losing its contents when no power is being supplied. Each of the programmable crosspoint devices (106) may be used to represent one or more bits of data. Although individual crossbar lines (108, 110) in FIG. 1 are shown with rectangular cross sections, crossbars may also have square, circular, elliptical, or more complex cross sections. The lines may also have many different widths, diameters, aspect ratios and/or eccentricities. The crossbars may be nanowires, sub-microscale wires, microscale wires, or wires with larger dimensions.

According to certain illustrative embodiments, the crossbar architecture (100) may be integrated into a Complimentary Metal-Oxide-Semiconductor (CMOS) circuit or other conventional computer circuitry. Each individual wire segment may be connected to the CMOS circuitry by a via (112). The via (112) may be embodied as an electrically conductive path through the various substrate materials used in manufacturing the crossbar architecture. This CMOS circuitry can provide additional functionality to the memristive device such as input/output functions, buffering, logic, configuration, or other functionality. Multiple crossbar arrays can be formed over the CMOS circuitry to create a multilayer circuit.

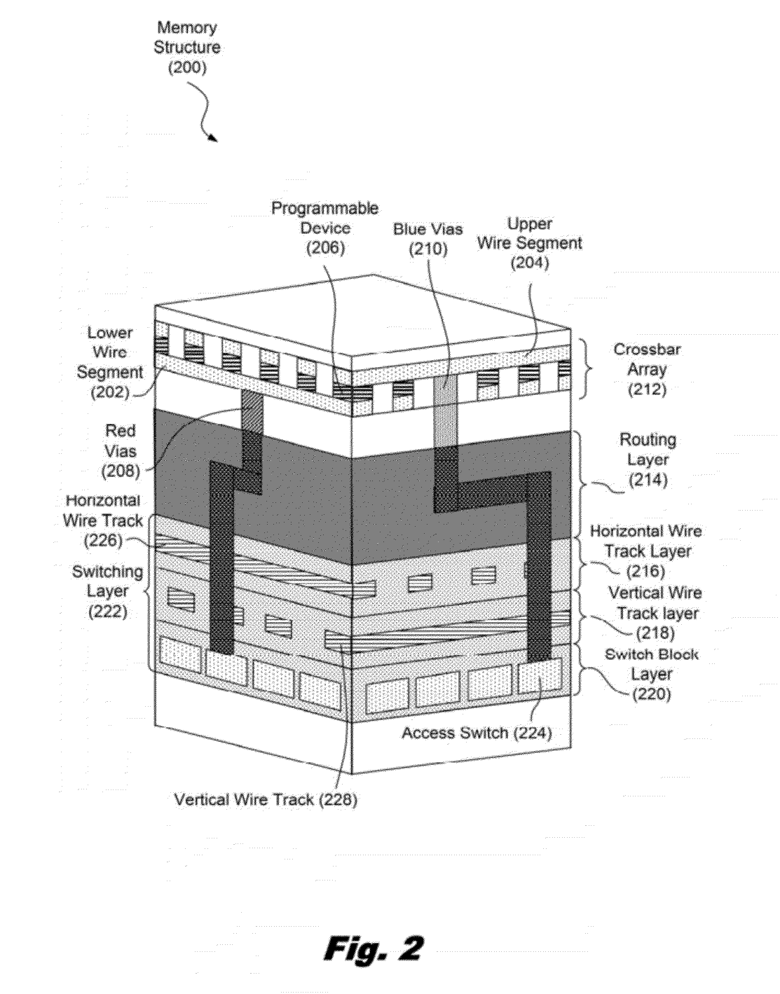

FIG. 2 is a diagram showing an illustrative memory structure (200). According to certain illustrative embodiments, a switching layer (222) may be connected to a crossbar array (212) through a routing interconnection layer (214). Red vias (208) may be used to connect the lower wire segments (202) of the crossbar array (212) to the routing interconnection layer and blue vias (210) may be used to connect the upper wire segments (204) of the crossbar array to the routing interconnection layer (214). The terms red vias and blue vias do not indicate a visual color of the vias. Rather, the terms are used as a matter of convention to distinguish between the types of wire segments to which they connect.

The switching layer (222) may be used to select which access vias are to be selected. By selecting particular access vias, specific wire segments may be selected. By selecting a specific lower wire segment (202) and a specific upper wire segment (204), a specific crosspoint including a programmable device (206) may be selected. As mentioned above, placing the access switches (224) directly beneath the access vias (208, 210) may limit the density of the memory array. This is because the location of the access vias is generally limited by the structure of the crossbar array (212) itself. Thus, by laying out the access switches (224) in an efficient manner and using a routing interconnection layer (214) to route the access switches to the appropriate access vias (208, 210), a higher density crossbar array (212) may be utilized.

The switching layer (222) may include a switch block layer (220) comprising the access switches (224), a vertical wire track layer (218), and a horizontal wire track layer (216). It should be noted that the layers illustrated in FIG. 2 are not necessarily drawn to scale. Additionally, the shapes presented in FIG. 2 are not necessarily indicative of shapes which may be present in a realized embodiment of the principles described herein. The various layers and shapes depicted in FIG. 2 are for illustrative purposes only.

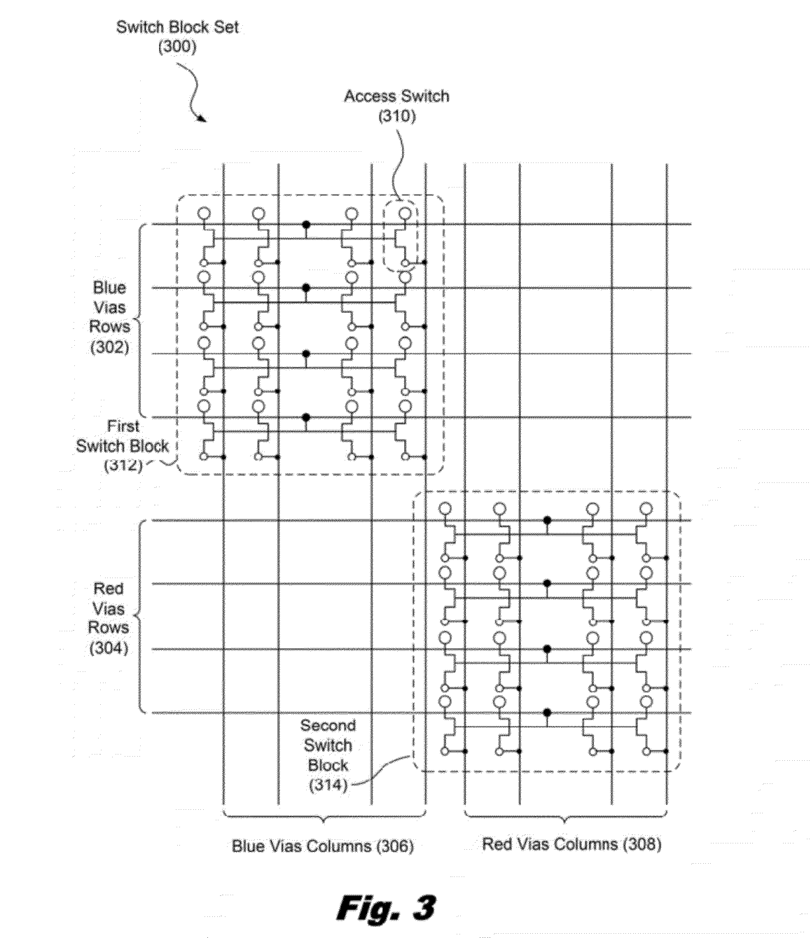

The switch block layer (220) includes the actual access switches (224) for selecting particular wire segments within the crossbar array (212). In some embodiments, the access switches (224) may be laid out in sets of two offset N×N blocks. More detail about the access switch layout will be discussed in greater detail below within the text accompanying FIG. 3.

The actual access switches (224) may comprise any suitable electrical switching device. One example of such a switching device is a transistor. One type of transistor which is typically used as a switching device is a Metal-Oxide Semiconductor Field Effect Transistor (MOSFET) device. A transistor typically includes three terminals; a gate, a drain, and a source. A MOSFET device may be either an N channel device or a P channel device. If the signal supplied to the gate of an N channel MOSFET device is high, then the transistor may be in an ON state, allowing electric current to pass between the drain and a source. If the signal at the gate of a P channel device is low, then the transistor may be in an ON state, allowing electric current to flow between the drain and a source. If a transistor is in an OFF state, then electric current is prohibited from flowing between the source and the drain.

Another type of transistor which may be used as a switching device is a Bipolar Junction Transistor (BJT) device. Although structured differently than a MOSFET device, a BJT device operates similarly to a MOSFET device. The three terminals of a BJT device are referred to as the base, the emitter and the collector. The base corresponds to the gate of a MOSFET device and the emitter and collector correspond to the drain and the source of a MOSFET device. The electric current flowing between the emitter and the collector is dependent upon the signal being supplied to the base of the BJT device.

The various terminals of the access switches (224) may be connected to horizontal wire tracks (226) and vertical wire tracks (228). The horizontal wire tracks (226) and vertical wire tracks (228) may be used to select particular access switches (224). For example, the access switches may be made of N channel MOSFET devices with a default state being an OFF state. Vertical wire tracks (226) may be connected to the source terminal of the access switches (224) and horizontal wire tracks (228) may be connected to the gate terminal of the access switches. The drain terminals may be connected to the access vias (208, 210) of the crossbar layer (212) through the routing interconnection layer (214).

In one example of operation for a memory structure (200) as depicted in FIG. 2, a vertical wire track and a horizontal wire track may be used to select a first access switch connected to a lower wire segment (202) through a red via (208). Likewise, a different vertical wire track and a different horizontal wire track may be used to select a second access switch connected to an upper wire segment (204) through a blue via (210). Thus, an electrical path may be formed across a specific programmable device (206) located at a crosspoint between the selected lower wire segment (202) and the selected upper wire segment (204). Through the formed electrical path, read/write circuitry may be used to either determine the state of the programmable device (206) or change the state of the programmable device (206). For example, a current sense amplifier connected to the vertical and horizontal wire tracks may be used to determine the state of the programmable device (206). Alternatively, electronic circuitry may be used to send a programming signal through the formed electrical path to change the state of the programmable device (206).

FIG. 3 is a diagram showing an illustrative set of two offset switch blocks. According to certain illustrative embodiments, the switch block layer may include a number of switch blocks laid out in two offset 4×4 blocks of access switches (310). A first switch block (312) from the switch block set (300) may include access switches (310) to be used to access connect to blue vias. Likewise, a second switch block (314) from the switch block set (300) may be used to connect to red vias.

The horizontal wire tracks connected to the access switches (310) of the first switch block (312) may be referred to as the blue vias rows (302). The vertical wire tracks connected to the access switches (310) of the first switch block (312) may be referred to as blue vias columns (306). Likewise, the horizontal wire tracks connected to the access switches (310) of the second switch block (314) may be referred to as red vias rows (304) and the vertical wire tracks connected to the access switches (310) of the second switch block (314) may be referred to as red vias columns (308). The blue vias rows (302) and the blue vias columns (306) may be used to select an access switch (310) connected to a blue access via and thus a lower wire segment from a crossbar array. Likewise, the red vias rows (304) and the red vias columns (308) may be used to select an access switch (310) connected to a red access via and thus an upper wire segment from the crossbar array.

A switch block set (300) having two 4×4 offset blocks as depicted in FIG. 3 may address a 16×16 crossbar array with a total of 256 crosspoints. As will be appreciated by one skilled in the relevant art, the set of two offset 4×4 blocks may consume much less space than if the access switches were laid out in two perpendicular lines, each line being 16 access switches long.

The switch blocks may not need to be laid out in a square manner as illustrated in FIG. 3. For example, one switch block may have dimensions of 2×8 and the other switch block may have dimensions of 8×2. Additionally, larger switch blocks may be used. For example, each switch block may have dimensions of 8×8. The size and dimensions of the switch block may vary depending on the design requirements and the structure of the crossbar array.

An addressing scheme as described above may be referred to as a four dimensional (4D) addressing scheme. This is because a total of four coordinates indicating four wire tracks are used to select a particular crosspoint in the crossbar array. More particularly, two row/column pairs are used to select a particular crosspoint. One row/column pair is used to select a lower wire segment and the other row/column pair is used to select an upper wire segment.

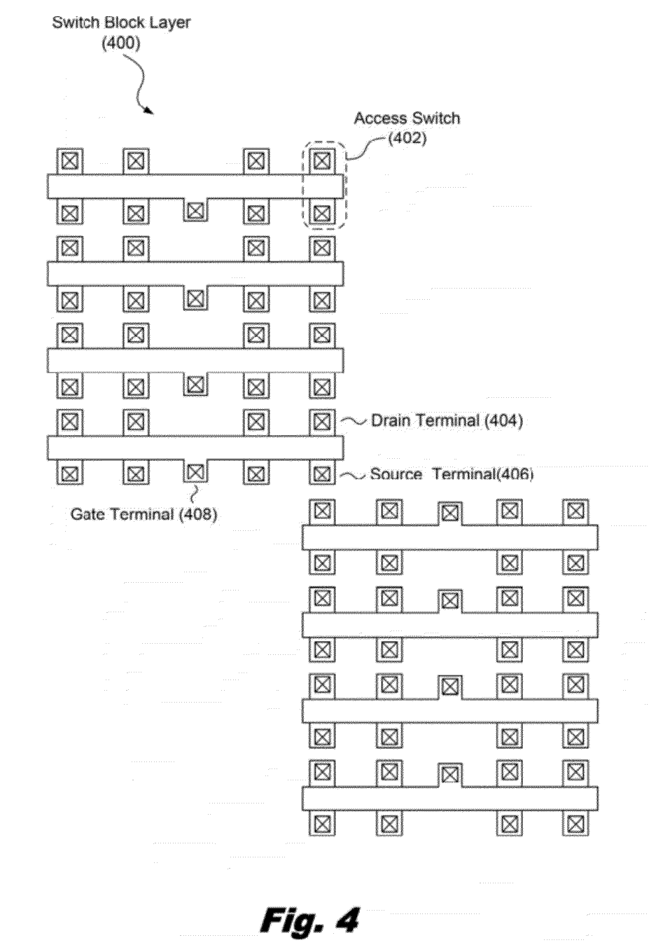

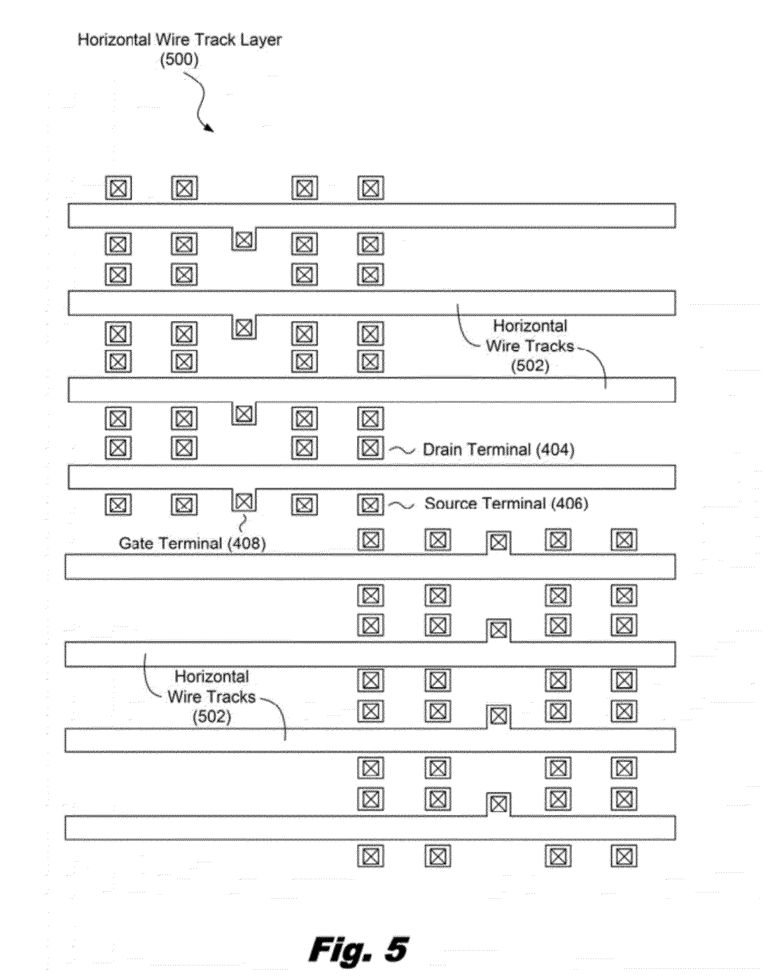

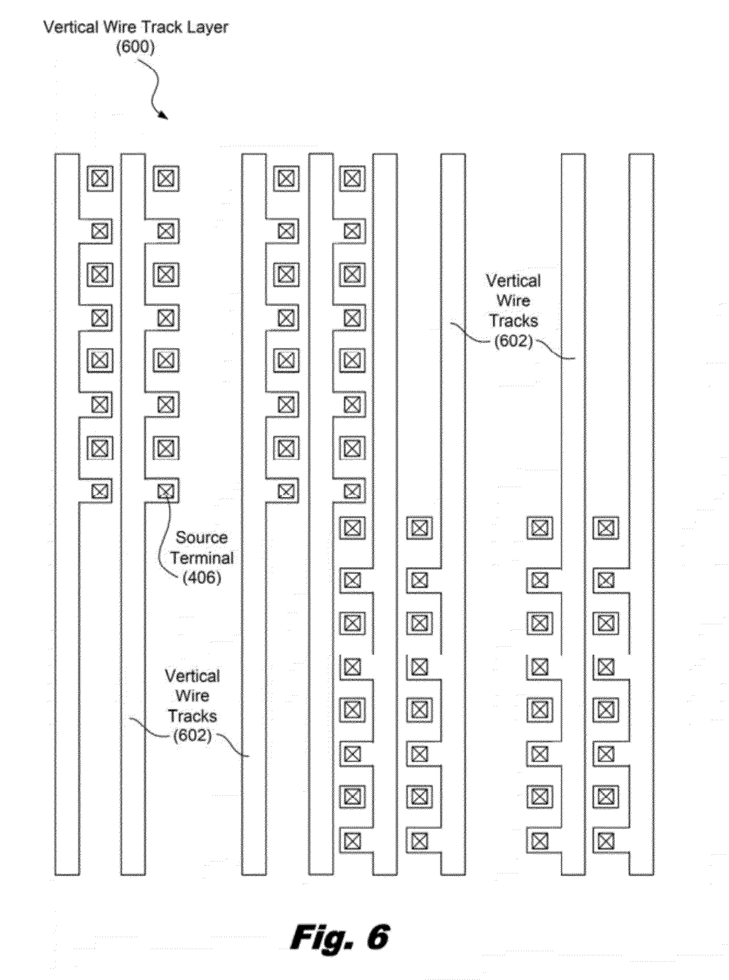

To provide an understanding of how the switching layer (222, FIG. 2) may be laid out within an integrated circuit substrate, the following three figures (FIG. 4, FIG. 5, and FIG. 6) illustrate an example of a switch block layer (220, FIG. 2) layout, a horizontal wire track layer layout (216, FIG. 2), and a vertical wire track layer (218) layout.

FIG. 4 is a diagram showing an illustrative top view of a switch block layer (400). According to certain illustrative embodiments, the switch block layer includes the actual electronic components which comprise the access switches. The access switches (402) may be laid out in a 4×4 configuration as shown in FIG. 4. Each access switch (402) may include a drain terminal (404) and a source terminal (406). In some embodiments, each row of four access switches (402) may share a gate terminal (408).

FIG. 5 is a diagram showing an illustrative top view of a horizontal wire track layer (500). According to certain illustrative embodiments, the horizontal wire tracks (502) may be laid out over the gate terminals in a manner so as to make contact with the gate terminals. Thus, each access switch from both switch blocks may be connected to a horizontal wire track (502). As will be appreciated by one skilled in the relevant art, the location of the wire tracks may be constrained based on the characteristics of the materials involved in manufacturing the integrated circuit which includes the crossbar array and accompanying read/write circuitry. The materials used to form the horizontal wire tracks may be any sufficiently electrically conductive material which may be typical in the art of integrated circuit fabrication.

The precise spacing between the source terminal contacts, the drain terminal contacts, and the horizontal wire tracks (502) are not necessarily drawn to scale. For example, an integrated circuit may be designed so that the spacing between the source terminal contacts and the horizontal wire tracks (502) is equal to the spacing between the drain terminal contacts and the horizontal wire tracks (502). Additionally, the same spacing between a drain terminal contact and an adjacent source terminal contact may be equal to the spacing between a source or drain contact and a horizontal wire track (502).

FIG. 6 is a diagram showing an illustrative top view of a vertical wire track layer (600). According to certain illustrative embodiments, the source terminal (406) of each access switch may be connected to a vertical wire track (602). The vertical wire tracks (602) may be laid out in a manner so as to run near the source terminal (406) of each access switch. A small stub of metallic material may protrude from each source terminal to connect to the vertical wire tracks (602). As with the horizontal wire tracks, the location of the vertical wire tracks (602) may be subject to a set of constraints based on the material used to manufacture the integrated circuit.

The spacing in FIG. 6 is not necessarily drawn to scale. For example, the spacing between the source contacts and the drain contacts may be the same as the spacing between the source/drain contacts and the vertical wire tracks (602).

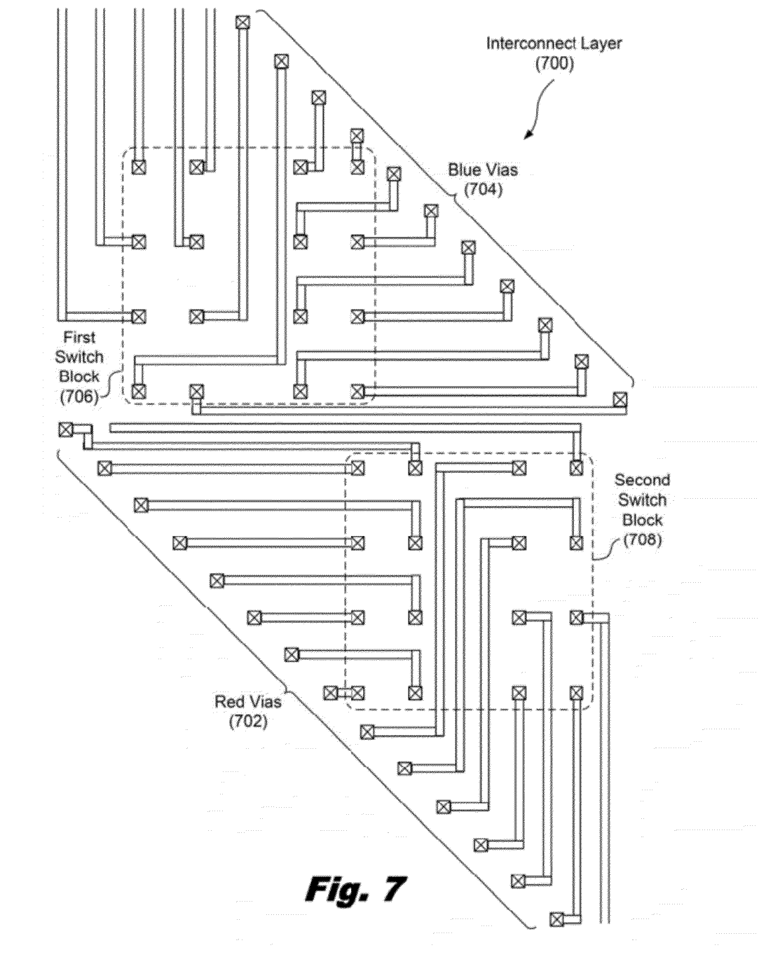

FIG. 7 is a diagram showing an illustrative top view of a routing interconnect layer (700) to connect to a disjointed crossbar array. As mentioned above, the routing interconnect layer may be used to connect the access switches to the access vias of the crossbar array. The use of the routing interconnect layer (700) allows the access switches to be laid out in an efficient manner independently of the location of the access vias of the crossbar.

According to certain illustrative embodiments, the routing interconnect layer (700) may be configured to route the access switches from a first switch block (706) to a diagonal line of blue vias (704). Likewise, the access switches from a second switch block (708) may be routed to a diagonal line of red vias (702). The diagonal placement of the red vias (702) and the blue vias (702) may be dependent upon the structure of the crossbar array.

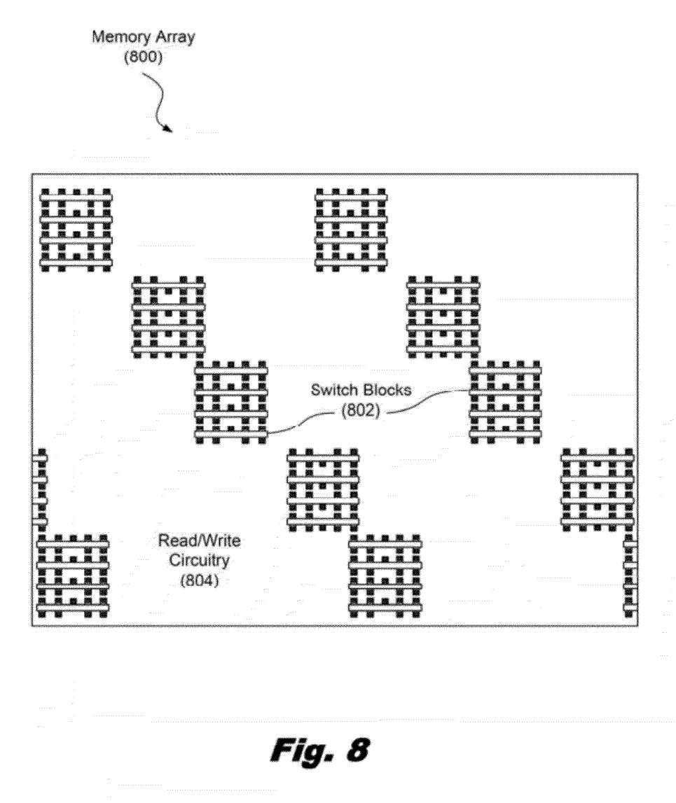

FIG. 8 is a diagram showing illustrative multiple sets of switch blocks for a memory array (800). According to certain illustrative embodiments, a memory array (800) may include several sets of offset switch blocks. Generally, memory arrays include millions of programmable devices to store the vast amounts of digital data required by modern processing systems. The pattern in which the switch blocks (802) are laid out may be dependent upon the structure of the overlying crossbar array. The pattern may also be designed to leave space between switch blocks for various read/write circuitry (804) such as decoders and sense amplifiers.

According to some illustrative embodiments, it may be helpful to limit the length of the horizontal and vertical wire tracks used for selecting the access switches. In some cases the switch blocks may not fit under a memory array if the number of access switches in a particular set of switch blocks is less than 32. In the case illustrated above, a set of switch blocks including a total of 32 access switches may allow room for read/write circuitry (804) between the diagonal rows of switch blocks (802).

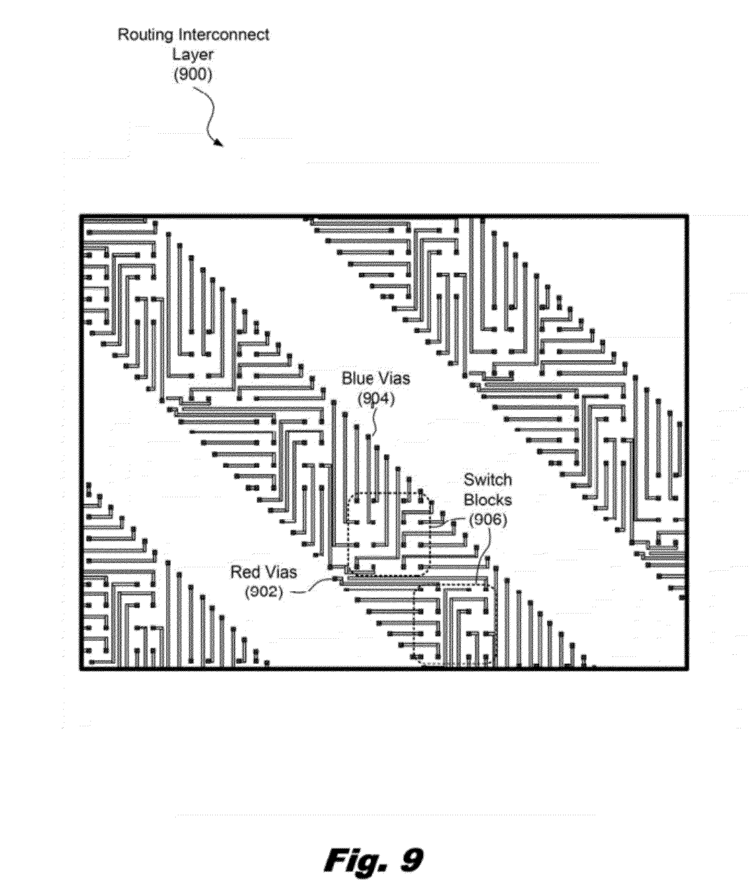

FIG. 9 is a diagram showing an illustrative routing interconnect layer (900) for a memory array having multiple sets of switch blocks. According to certain illustrative embodiments, the routing interconnect layer (900) may include long diagonal lines of red vias (902) and blue vias (904). Each line may be connected to access switches from several switch blocks (906). Similarly to the switch blocks shown in FIG. 8, the routing lines shown in FIG. 9 are not necessarily illustrating a complete memory array. A typical memory array may include millions of switch blocks associated with programmable logic devices. Additionally, the dimensions shown in FIG. 9 are not necessarily to scale of a realized fabrication of a memory array embodying principles' described herein. Furthermore, the lines of red vias (902) and blue vias (904) are not limited to the diagonal pattern illustrated in FIG. 9. The diagonal pattern shown is for one type of disjointed crossbar structure.

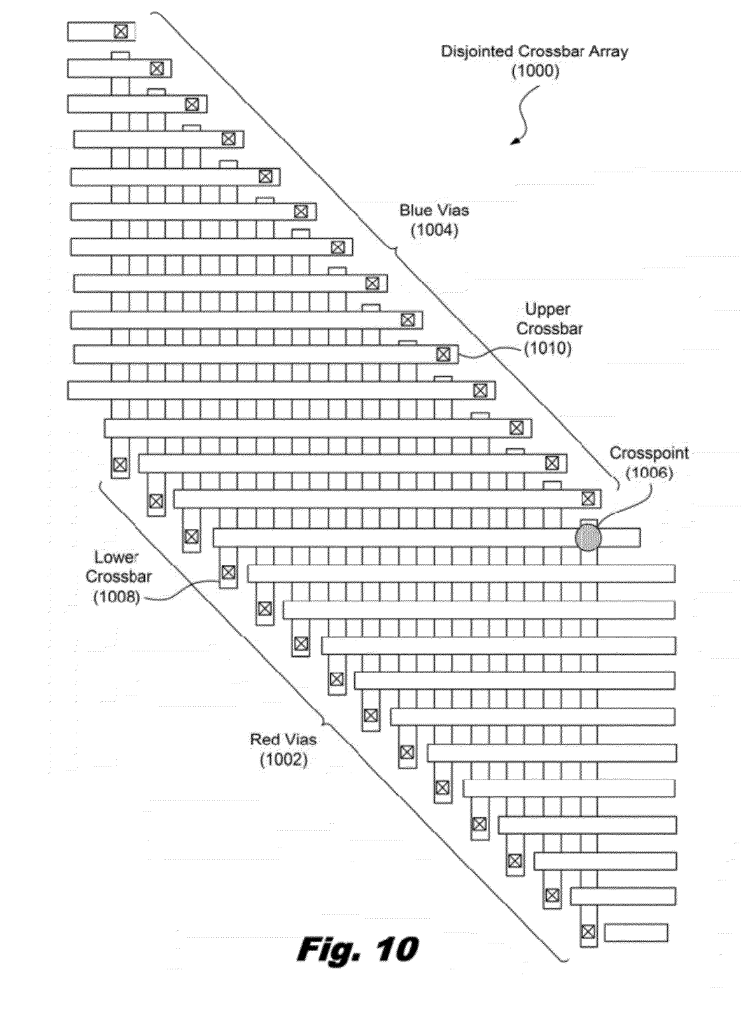

FIG. 10 is a diagram showing an illustrative disjointed crossbar array. According to certain illustrative embodiments, a crossbar array may be laid out in a disjointed fashion. A disjointed crossbar array (1000) may be one in which the end crosspoints of an upper wire segment do not intersect the same lower wire segments as the end crosspoints of an adjacent parallel upper wire segment. There may be many ways to arrange a disjointed crossbar array (1000). One way of arranging a disjointed crossbar array (1000) is to shift each upper crossbar (1010) down one crosspoint distance from the neighboring parallel upper crossbar (1010) to the left. A crosspoint distance may be defined as the distance between two adjacent crosspoints (1006) along the same wire segment. Similarly each lower crossbar (1008) may be shifted one crosspoint distance to the right of the parallel lower crossbar above it.

Such an arrangement may result in two diagonal lines in which vias are placed. The red vias (1002) may be placed along a diagonal line connecting to the lower crossbars (1008). Likewise the blue vias (1004) may be placed along a diagonal line and be connected to the upper crossbars (1010). The pattern of the red vias (1002) and blue vias (1004) matches the pattern of the positions of the red vias and blue vias of the routing interconnect layer illustrated in FIG. 7.

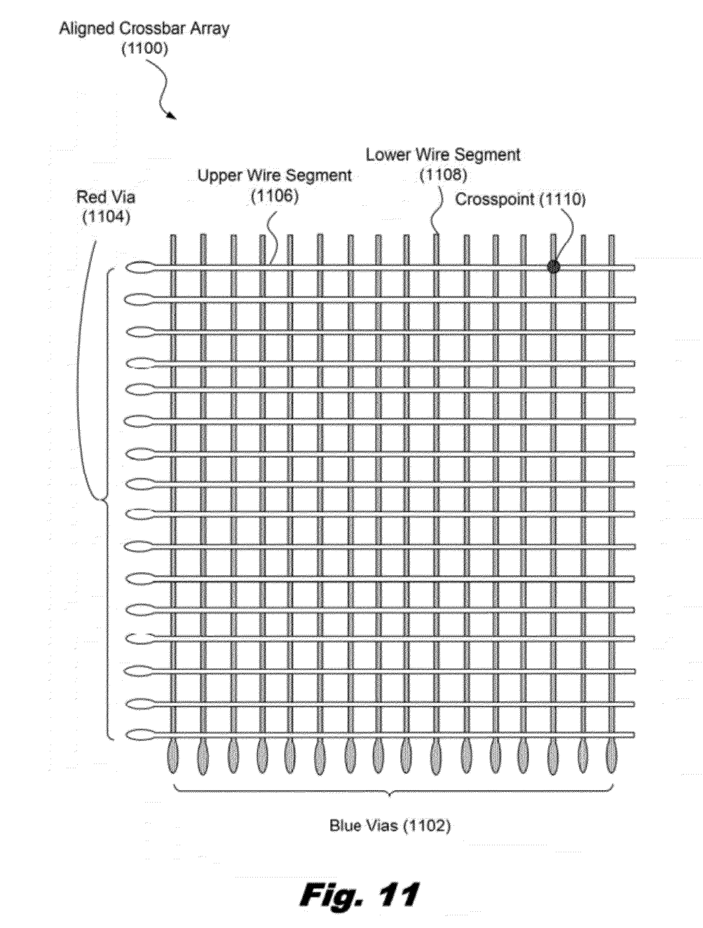

FIG. 11 is a diagram showing an illustrative aligned crossbar array (1100). According to certain illustrative embodiments, a crossbar array may be arranged in a manner such that the end crosspoints of an upper wire segment (1106) intersect the same lower wire segments (1108) as the end crosspoints of an adjacent upper wire segment (1106). Red vias (1104) may be connected to the ends of the upper wire segments (1106). Likewise, blue vias (1102) may be connected to the ends of the lower wire segments (1108). As with the typical crossbar array, a programmable logic device may be placed at each crosspoint (1110).

The access vias (1102, 1104) may be connected to the access switches through the routing interconnect layer. The routing interconnect layer may be designed so as to route signals from set of two offset switch blocks as illustrated in FIG. 4 to the two perpendicular lines of access vias (1102, 1104) shown in FIG. 11.

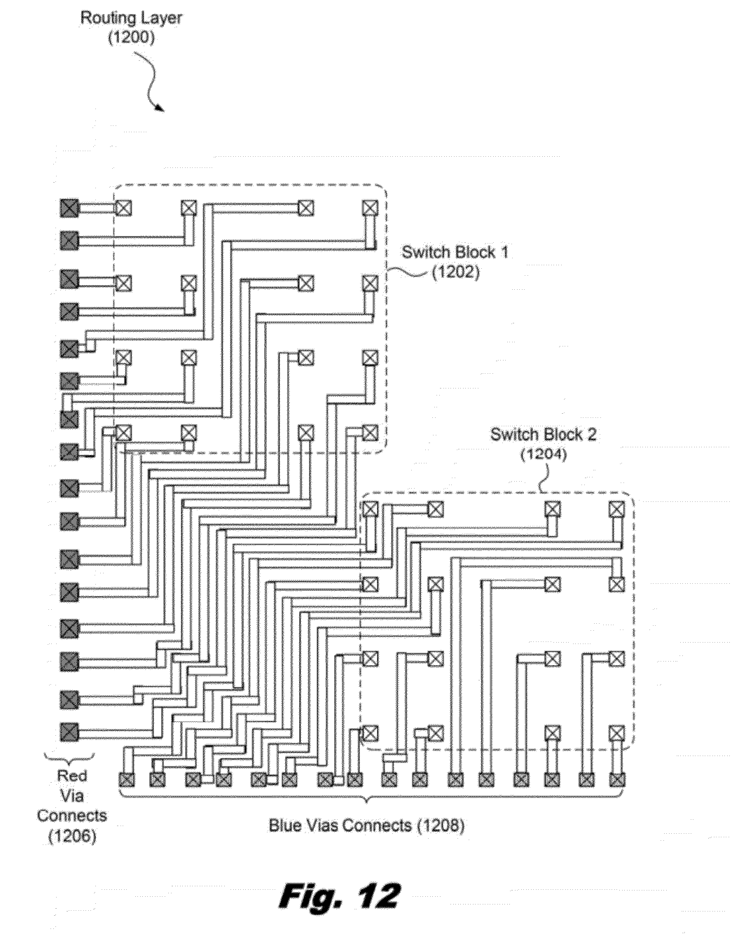

FIG. 12 is a diagram showing an illustrative routing layer (1200) for an aligned crossbar array. According to certain illustrative embodiments, the routing layer (1200) may be configured to route signals from a terminal of each access switch in switch block 1 (1202) to a line of red via connects (1206) which may be connected to the red vias (1104, FIG. 11) connected to an aligned crossbar array (1100, FIG. 11). Likewise, a terminal of each access switch in switch block 2 (1204) may be routed to a line of blue via connects (1208) which may be connected to the blue vias (1102, FIG. 11) connected to an aligned crossbar array (1100, FIG. 11).

As mentioned above, the routing layer allows the access switches to be placed in a manner independent of the access vias of the crossbar array. Thus, the access switches may be placed in an efficient manner that consumes less physical space on an integrated circuit. As a result, the crossbar array may be built on a smaller scale, thus providing a higher density memory array.

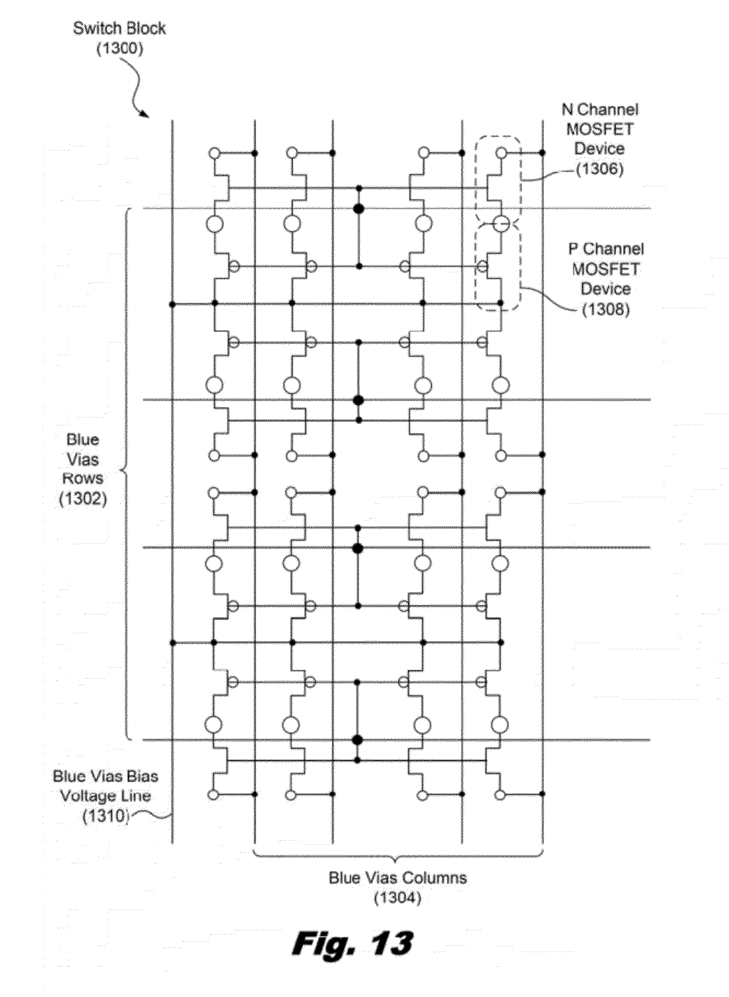

FIG. 13 is a diagram showing an illustrative switch block (1300) with access switches having both an N channel MOSFET device (1306) and a P channel MOSFET device (1308). Such an access switch may be referred to as a complimentary gate. The switch block may also include an unselected blue vias bias voltage line (1310)

As mentioned above, an N channel MOSFET device (1306) may allow electrical current to flow between the drain terminal and the source terminal when the signal being received at the gate terminal is a high voltage signal. Conversely, a P channel MOSFET device (1308) may allow electrical current to flow between the drain terminal and the source terminal when the signal being received by the gate terminal is a low voltage signal.

The precise range of voltage used to distinguish between high and low voltage signals may depend on the characteristics of the transistors and other circuit elements on an integrated circuit. For example, a particular integrated circuit may be designed so that a low voltage may range from 0 to 0.2 volts. Additionally, a high voltage signal may range between 0.8 volts and 1.2 volts.

The N channel MOSFET device (1306) and the P channel MOSFET device (1308) may be connected in parallel and in a complimentary manner. That is, the signal being supplied to the gate terminal of the N channel MOSFET device (1306) may also be connected to the gate terminal of the P channel MOSFET device (1308). However, the signal being supplied to the P channel MOSFET device (1308) may be inverted. An inverter may switch a low signal to a high signal and vice versa.

During operation of the complimentary switches, the N channel MOSFET devices (1306) along a particular row may be selected when a high voltage signal is applied to a blue via row. All other blue via rows remain unselected, having a low voltage signal applied. This may cause the P channel MOSFET devices (1308) which are complimentary to the unselected N channel MOSFET devices (1306) to connect the deselected blue vias to the blue vias bias voltage line (1310).

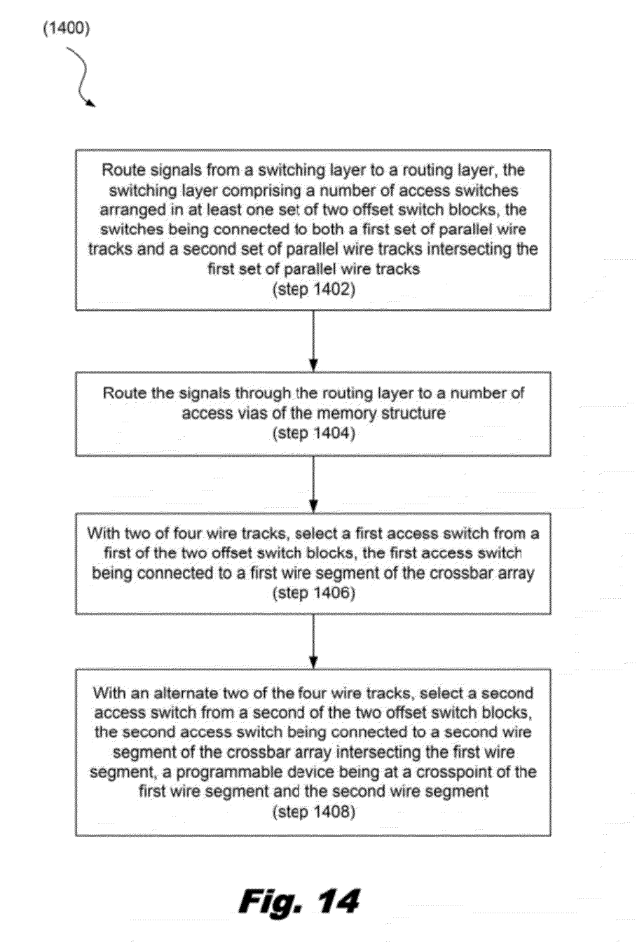

FIG. 14 is a flow chart showing an illustrative method for connecting read/write circuitry to a memory structure. According to certain illustrative embodiments, the method (1400) may include routing (step 1402) signals from a switching layer to a routing layer, the switching layer comprising a number of access switches arranged in at least one set of two offset switch blocks, the access switches being connected to a first set of parallel wire tracks and a second set of parallel wire tracks intersecting the first set of parallel wire tracks; and routing (step 1404) the signals through the routing layer to a number of access vias of the memory structure; in which four wire tracks are used to select a programmable device of the memory structure. The method may further include selecting (step 1406), with two of four wire tracks, a first access switch from a first of the two offset switch blocks, the first access switch being connected to a first wire segment of the crossbar array; and selecting (step 1408), with an alternate two of the four wire tracks, a second access switch from a second of the two offset switch blocks, the second access switch being connected to a second wire segment of the crossbar array intersecting the first wire segment, a programmable device being at a crosspoint of the first wire segment and the second wire segment.

In sum, through use of a system or method embodying principles described herein, the access switches may be laid out independent of the associated memory structure. Thus, the access switches may be laid out in a more condensed and efficient manner. As a result, a memory structure may be designed on a smaller scale, thus providing more memory storage space within a smaller amount of physical space.

The preceding description has been presented only to illustrate and describe embodiments and examples of the principles described. This description is not intended to be exhaustive or to limit these principles to any precise form disclosed. Many modifications and variations are possible in light of the above teaching.

What is claimed is:

1. An interconnect architecture for connecting read/write circuitry to a memory structure, the interconnect architecture comprising:
a switching layer comprising a number of access switches arranged in at least one set of two offset switch blocks, said access switches being connected to a first set of parallel wire tracks and a second set of parallel wire tracks intersecting said first set of parallel wire tracks; and
a routing layer connecting said access switches to a number of access vias of said memory structure;
in which four wire tracks are used to select a programmable device of said memory structure.

2. The interconnect architecture of claim 1, in which said memory structure is a crossbar array and said four wire tracks are used to select one access switch from each of said two offset switch blocks, one of said selected access switches being connected to a first wire segment of said crossbar array and one of said selected access switches being connected to a second wire segment of said crossbar array intersecting said first wire segment, said programmable device being at a crosspoint of said first wire segment and said second wire segment.

3. The interconnect architecture of claim 1, in which said memory structure is a disjointed crossbar array.

4. The interconnect architecture of claim 3, in which said routing layer is configured to route signals from said access switches into a diagonal pattern to access vias of said disjointed crossbar array.

5. The interconnect architecture of claim 1, in which said memory structure is an aligned crossbar array.

6. The interconnection architecture of claim 5, in which said routing layer is configured to route signals from said access switches along two perpendicular lines to connect to access vias of said aligned crossbar array.

7. The interconnect architecture of claim 1, in which said memory structure is one of: a memristive crossbar array and a memcapacitive crossbar array.

8. The interconnect architecture of claim 1, in which at least one of said access switches comprises a P channel MOSFET device and an N channel MOSFET device connected in a complimentary manner.

9. A method for connecting read/write circuitry to a memory structure, the method comprising:
routing signals from a switching layer to a routing layer, said switching layer comprising a number of access switches arranged in at least one set of two offset switch blocks, said access switches being connected to a first set of parallel wire tracks and a second set of parallel wire tracks intersecting said first set of parallel wire tracks; and
routing said signals through said routing layer to a number of access vias of said memory structure;
in which four wire tracks are used to select a programmable device of said memory structure.

10. The method of claim 9, in which said memory structure is a crossbar array, said method further comprising:
with two of said four wire tracks, selecting a first access switch from a first of said two offset switch blocks, said first access switch being connected to a first wire segment of said crossbar array; and
with an alternate two of said four wire tracks, selecting a second access switch from a second of said two offset switch blocks, said second access switch being connected to a second wire segment of said crossbar array intersecting said first wire segment, said programmable device being at a crosspoint of said first wire segment and said second wire segment.

11. The method of claim 9, in which said memory structure is one of: a disjointed crossbar array and an aligned crossbar array.

12. The method of claim 11, in which said routing layer is configured to route said signals in one of: a diagonal pattern to access vias of said disjointed crossbar array and a two perpendicular line pattern to access vias of said aligned crossbar array.

13. The method of claim 9, in which said memory structure is one of: a memristive crossbar array and a memcapacitive crossbar array.

14. The method of claim 9, in which at least one of said access switches in said switching layer comprises a P channel MOSFET device and an N channel MOSFET device connected in a complimentary manner.

15. A computer memory system comprising:
a crossbar memory structure; and
a routing layer configured to:
route signals through a switching layer of said routing layer, said switching layer comprising a number of access switches arranged in at least one set of two offset switch blocks, said access switches being connected to a first set of parallel wire tracks and a second set of parallel wire tracks intersecting said first set of parallel wire tracks; and
route said signals through said routing layer to a number of access vias of said crossbar memory structure;
in which four wire tracks are used to select a programmable device located at a crosspoint of said crossbar memory structure.
